(19) United States
(12) Patent Application Publication
(10) Pub. No.: US 2002/0174391 A1
(43) Pub. Date: Nov. 21, 2002

(54) Method of testing semiconductor storage device

(75) Inventor: Takashi Yamada, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/000,160

(22) Filed: Dec. 4, 2001

(30) Foreign Application Priority Data
May 18, 2001 (JP) 2001-149214

(51) Int. Cl. G11C 29/00

(52) U.S. Cl. 714/718

(57) ABSTRACT

A plurality of test patterns are set in a tester for testing semiconductor storage devices. Different test patterns are applied to respective semiconductor storage devices connected to the tester. A determination is made as to whether or not results of the tested semiconductor storage devices fall within a predetermined tolerance.

### BACKGROUND OF THE INVENTION

1. Field of the Invention

The present invention relates to a method of testing a semiconductor storage device.

2. Background Art

FIG. 3 is a schematic diagram for illustrating a related-art method of testing a semiconductor storage device. In the drawing, reference numeral 1 designates a semiconductor storage device under test. As is well known, a plurality of semiconductor memory cells 2 are arranged along bit lines and column lines.

Reference numerals 3 and 4 designate redundant lines provided in suitable number to the bit and column lines. Reference numeral 5 designates a terminal for receiving power, a signal, and a test pattern at the time of test operation and for transmitting a test result. Reference numeral 6 designates a tester f or testing the semiconductor storage device 1. The tester 6 has a power terminal 7 f or supplying power to the semiconductor storage device 1; a signal terminal 8 f or supplying a test signal and a test pattern; and a result output terminal 9 for receiving the test result output from the semiconductor storage device 1.

FIG. 4 is a flowchart showing the related-art test method, wherein a nonvolatile storage device is to be tested. In step S41, a test is commenced. In step S42, an erasure test is performed. The test is performed by means of subjecting all semiconductor storage devices under test connected to the tester 6 to identical voltages for identical periods of time. Further detailed explanations of the test will be provided later. In step S43, a writing test is performed.

The test is identical with an erasure test (step S42), except for a difference between an erasure operation and a writing operation. Through the erasure test (step S42) and the write test (step S43), testing is completed in step S44.

FIG. 5 is a flowchart showing test procedures of the erasure test (step S42) shown in FIG. 4. In step S51, a test is commenced. In step S52, a predetermined voltage pulse and a signal are applied to all the semiconductor storage devices (memory cells) for a predetermined period of time, thereby effecting collective writing operation.

FIG. 6 shows the distribution of a threshold value (Vth) of the semiconductor storage device under test after writing, and the distribution of the threshold value of the semiconductor storage device after erasure. The vertical axis represents the number of memory cells, and the horizontal axis represents Vth.

Reference numeral 61 designates a distribution of the threshold value after step S52.

In step S53, a pulse which differs in voltage level from that used for writing is applied to the semiconductor storage devices for a predetermined period of time, thereby collectively erasing all the memory cells. At this time, the threshold value Vth also changes. Hence, as indicated by arrow 62 shown in FIG. 6, the distribution of the threshold value Vth after erasure shifts leftward.

In step S54, a lead test is performed, thereby checking threshold values Vth of individual semiconductor storage devices under test. Then, the distribution of Vth after erasure operation is ascertained.

The threshold values Vth shift in the direction designated by arrow 62 shown in FIG. 6 during the course of progress from a writing phase to an erasure phase. However, the speed of change in the threshold values Vth differs from one semiconductor storage device to another. The distribution of the threshold values Vth after erasure phase varies, as designated by 63, 64, and 65 shown in FIG. 6.

Reference numeral 66 designates a tolerance of high level; and 67 designates a tolerance of low level.

The distribution 63 corresponds to a center characteristic falling within the tolerance. In this case, a defective bit 68 and a defective line 69 of an anomalous distribution fall outside the tolerance. Reference numerals 64 and 65 designate characteristics that go outside the tolerance.

In step S55 shown in FIG. 5, redundancy analysis is performed. By means of a contrast between the distribution of the threshold values Vth after the erasure phase and tolerances 66 and 67, the number of defective bit and column lines is checked. A determination is made as to whether or not the defective bit and column lines are greater in number than redundant lines (3 and 4 shown in FIG. 3). When the defective bit and column lines are lesser in number than the redundant lines, there is made a determination on restoring all the defective bit and column lines by replacing the bit and column lines with the redundant lines 3 and 4. In a case where the defective bit and column lines are greater in number than the redundant lines, the defective bit and column lines equal in number to the redundant lines 3 and 4 are restored by being replaced with the redundant lines 3 and 4.

In the case shown in FIG. 6, a small number of defective bit lines show an anomalous distribution 68, and a small number of defective column lines show an anomalous distribution 69. Hence, the distribution 63 enables restoration of the defective bit and column lines by means of replacing the bit and column lines with redundant lines. However, in relation to the distribution 64, a large number of defective bit and column lines exist outside the tolerance of high level 66. In relation to the distribution 65, a large number of defective bit and column lines fall outside the tolerance of low level 67. Hence, restoration of all the defective bit and column lines by replacement of the bit and column lines with redundant lines is impossible.

In step S56, the semiconductor storage devices under test having the defective bit and column lines, which could not have been restored by the redundant lines, are determined to be defective. In step S57, the test is completed.

The method of testing related-art semiconductor storage devices is implemented in the manner as mentioned above. All semiconductor storage devices are tested under the same conditions; that is, at a given voltage and a given period of time. A voltage level is changed once during the course of progress from collective writing operation to collective erasure operation and vice versa. A lead test is performed in accordance with the distribution of the threshold values Vth determined by the thus-changed voltage level. Hence, there arises a problem of a characteristic of a semiconductor storage device being likely to go out of tolerance as a result of, e.g., an increase in the width of distribution of threshold values Vth or a distribution which has a narrow width but whose position varies greatly.

Further, the width of a distribution recently tends to become smaller, because of miniaturization. In addition to a tendency toward a smaller tolerance, the number of memory cells is increased in association with an increase in storage capacity, thereby resulting in a wider distribution. Hence, there also arises a problem of a characteristic of a semiconductor storage device becoming likely to go out of tolerance.

### SUMMARY OF THE INVENTION

The present invention has been conceived to solve the problem set forth. The present invention is aimed at providing a method of testing a semiconductor storage device which subjects a plurality of semiconductor storage devices to an optimized test, thereby restoring a considerable number of semiconductor storage devices, which would otherwise been determined to be defective under the related-art test method.

According to one aspect of the present invention, a method of testing a semiconductor storage device comprises the following steps. Firstly a plurality of test patterns are set in a tester for testing semiconductor storage devices. Secondly different test patterns are applied to respective semiconductor storage devices connected to said tester. Thirdly it is determined whether or not results of the tested semiconductor storage devices fall within a predetermined tolerance.

Hence, from among semiconductor storage devices which have been determined to be unrestorable under the related-art test method, a considerable number of semiconductor storage devices can be restored.

Other and further objects, features and advantages of the invention will appear more fully from the following description.

### BRIEF DESCRIPTION OF THE DRAWINGS

FIG. 1 is a flowchart showing a test method according to the first embodiment.

FIG. 2 is a flowchart showing a test method according to the second embodiment.

FIG. 3 is a schematic diagram for illustrating a related-art method of testing a semiconductor storage device.

FIG. 4 is a flowchart showing the related-art test method, wherein a nonvolatile storage device is to be tested.

FIG. 5 is a flowchart showing test procedures of the erasure test (step S42) shown in FIG. 4.

FIG. 6 shows the distribution of a threshold value (Vth) of the semiconductor storage device under test after writing, and the distribution of the threshold value of the semiconductor storage device after erasure.

### DETAILED DESCRIPTION OF THE PREFERRED EMBODIMENTS

First Embodiment

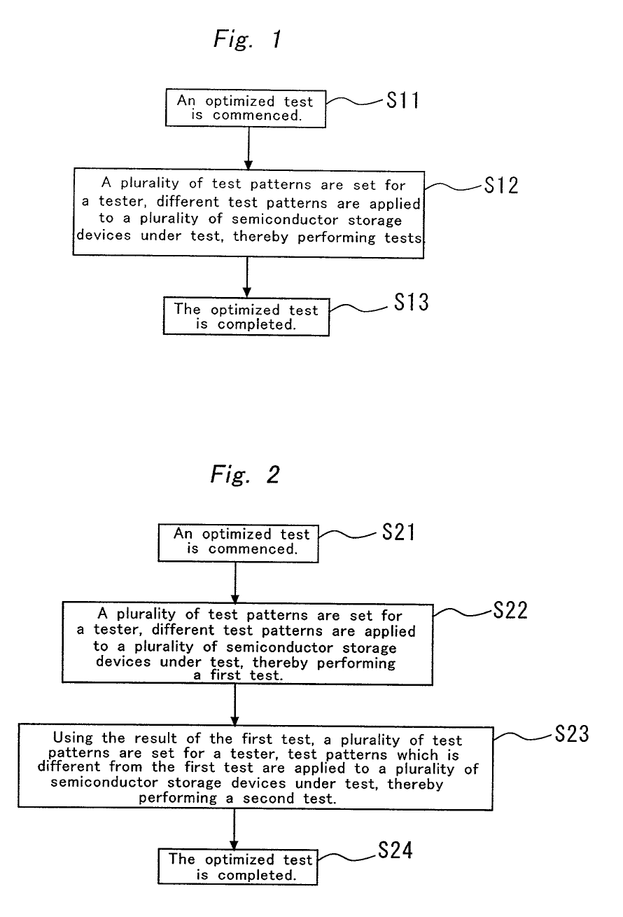

A first embodiment of the present invention will now be described hereinbelow by reference to FIG. 1.

FIG. 1 is a flowchart showing a test method according to the first embodiment. In step S11, a test is commenced. In step S12, a plurality of test patterns are set for a tester. Tests are performed by means of applying different test patterns to a plurality of semiconductor storage devices under test connected to the tester.

In some cases, different test patterns are applied to respective semiconductor storage devices. However, in another case, identical test patterns are applied to a limited number of semiconductor storage devices.

In this respect, the test method according to the present invention differs from the related-art test method which performs a test under the same conditions by means of applying a single test pattern to all semiconductor storage devices under test.

The method of the present invention is identical with the related-art method in terms of the manner of checking threshold values Vth of the semiconductor storage devices through a lead test, and of analyzing redundancy and determining whether or not the semiconductor storage devices are defective on the basis of the thus-checked threshold values. Hence, its repeated explanation is omitted, and the test is completed in step S13.

In the embodiment, different test patterns are applied to respective semiconductor storage devices, thereby optimizing test conditions. As a result, from among semiconductor storage devices which have been determined to be unrestorable by the related-art test method, a considerable number of semiconductor storage devices can be restored.

Second Embodiment

A second embodiment of the present invention will now be described by reference to the accompanying drawings.

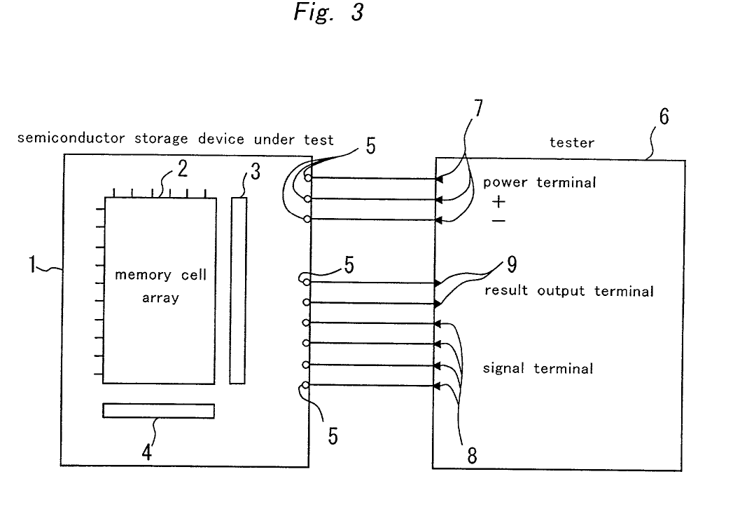

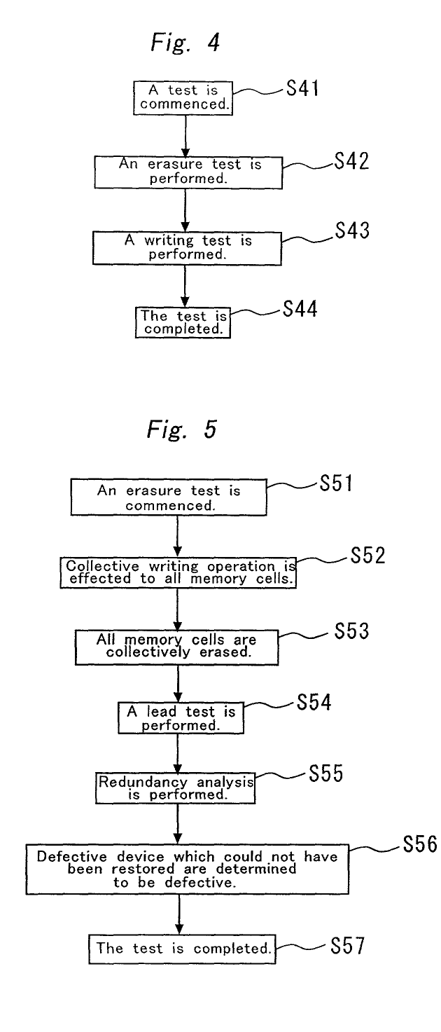

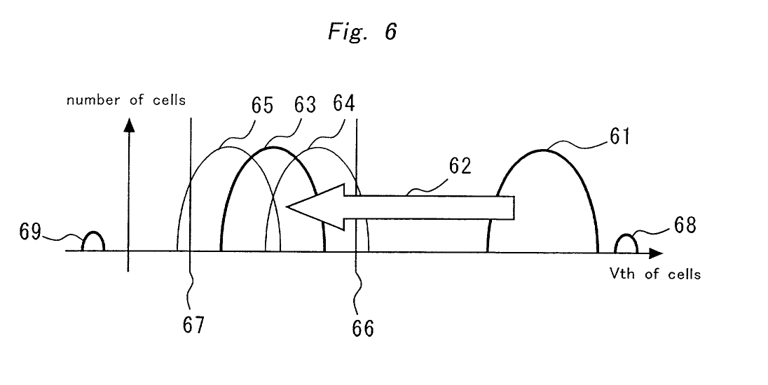

FIG. 2 is a flowchart showing a test method according to the second embodiment. More specifically, in the second embodiment, a plurality of tests are set, and semiconductor storage device—which have been determined to be effective through all the tests and by virtue of restoration using redundant bit and column lines—are determined to be non-defective.

In FIG. 2, for example, a test is performed twice.

More specifically, in step S21 a test is commenced. In step S22, a plurality of test patterns are set for a tester, as in the case of the first embodiment. Different test patterns are applied to respective semiconductor storage devices connected to the tester, thereby performing a first test.

In some cases, different test patterns are applied to respective semiconductor storage devices. However, there may be a case where identical test patterns are applied to a limited number of semiconductor storage devices.

Even this test is identical with the related-art test method in terms of the manner of checking threshold values Vth of the semiconductor storage devices through a lead test, and of analyzing redundancy and determining whether or not the semiconductor storage devices are defective on the basis of the thus-checked threshold values. Hence, its repeated explanation is omitted. In step S23, a plurality of semiconductor storage devices determined to be effective in the first test, including semiconductor storage devices that have been restored in the first test, are subjected to a second test through use of the result of the first test and a test pattern differing from that employed in the first test. The second test is identical with the first test in terms of procedures and a determination method.

The semiconductor storage devices that have been determined to be effective even in the second test are determined to be non-defective, and the test is completed in step S24.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-149214, filed on May 18, 2001 including specification, claims, drawings and summary, on which the Convention priority of the present application is based, are incorporated herein by reference in its entirety.

1. A method of testing a semiconductor storage device, comprising the steps of:
setting a plurality of test patterns in a tester for testing semiconductor storage devices;
applying different test patterns to respective semiconductor storage devices connected to said tester; and
determining whether or not results of the tested semiconductor storage devices fall within a predetermined tolerance.

2. The method of testing a semiconductor storage device according to claim 1, wherein the number of defective bit lines of said tested semiconductor storage device having exceeded a tolerance is compared with the number of redundant lines on the basis of a test result output, thereby determining semiconductor storage devices which can be restored through use of redundant lines.

3. The method of testing a semiconductor storage device according to claim 1, wherein the number of defective column lines of said tested semiconductor storage device having exceeded a tolerance is compared with the number of redundant lines on the basis of a test result output, thereby determining semiconductor storage devices which can be restored through use of redundant lines.

4. The method of testing a semiconductor storage device according to claim 1, wherein a test is performed several times while a test pattern is changed.

5. The method of testing a semiconductor storage device according to claim 1, wherein, when said tested semiconductor storage devices are non-volatile, the devices are subjected to writing and erasure tests.

6. The method of testing a semiconductor storage device according to claim 1, wherein a test pattern is made by combination of a voltage, a time, and a signal.
